(19) United States
(12) Patent Application Publication
(10) Pub. No.: US 2012/0044617 A1
(43) Pub. Date: Feb. 23, 2012

(54) PANEL MODULE WITH SIMPLIFIED SUPPORTING STRUCTURE AND PORTABLE ELECTRONIC APPARATUS THEREWITH

(76) Inventor: Wen-Kuo Lo, Hsin-Chu (TW)

(21) Appl. No.: 12/885,582

(22) Filed: Sep. 20, 2010

(30) Foreign Application Priority Data
Aug. 19, 2010 (TW) 099127711

(51) Int. Cl. H05K 7/00

(52) U.S. Cl. 361/679.01

(57) ABSTRACT

A panel module with simplified supporting structure and a portable electronic apparatus with the panel module are disclosed. The portable electronic apparatus includes a casing where the panel module is disposed. The panel module includes a frame and a bracket. The frame includes a reverse U-shaped passage. A display panel is fixed on the frame. The bracket includes a reverse U-shaped body and a plurality of fixing parts connected to the reverse U-shaped body. The reverse U-shaped body is accommodated in the reverse U-shaped passage. The fixing parts protrude out of the frame. The panel module is fixed on the casing by the fixing parts. Therefore, the invention uses the bracket with the reverse U-shaped structure to directly provide required fixedness and structure rigidity for the frame, so that an additional metal frame in the prior art for fixing a display panel together with a plastic frame can be omitted.

### BACKGROUND OF THE INVENTION

1. Field of the Invention

The invention relates to a panel module and a portable electronic apparatus therewith and especially relates to a panel module with a simplified supporting structure and a portable electronic apparatus therewith.

2. Description of the Prior Art

As the technology of manufacturing display panels improves, the size of the display panel becomes larger and larger. The stiffness provided by only a panel plastic frame is insufficient obviously for the whole panel with layer structure. Therefore, the plastic frame nowadays supporting an LCD panel and a backlight panel is often added with a metal frame, which not only strengthens the fixity between the panels and the plastic frame but also enhance the stiffness of the whole panel module. During assembling the panel module to an electronic apparatus, a bracket consisting of two independent connection parts is required to connect two sides of the metal frame and a casing of the electronic apparatus, so as to achieve the purpose of fixing the panel module in the electronic apparatus.

Obviously, the panel module nowadays uses two independent members to satisfy the requirements of the stiffness and the fixity of the whole panel module. The design thereof can simplify the complexity of single component, but the quantity of components and the manufacturing cost thereof increase. Furthermore, as the quantity of the components increases, the failure modes for products also increase, which is disadvantageous to monitoring the assembly processes and improving the product yield.

### SUMMARY OF THE INVENTION

An objective of the invention is to provide a panel module, whose supporting structure is simplified and uses fewer components than the prior art to achieve the required fixity and structure stiffness of the panel module.

The panel module is disposed in an electronic apparatus such as a portable electronic apparatus. The panel module includes a frame and a bracket. The frame includes a reverse U-shaped passage. The bracket includes a reverse U-shaped body and a plurality of fixing parts connected to the reverse U-shaped body. The reverse U-shaped body is accommodated in the reverse U-shaped passage. The fixing parts protrude out of the frame. The panel module is disposed on a casing of the electronic apparatus by the fixing parts.

The bracket used by the panel module shows to be reverse U-shaped and can provide a certain degree of structure stiffness; on the contrary, such effect does not appear on the two independent connection parts in the prior art. Therefore, the bracket of the panel module can be joined to the frame directly to provide the required structure stiffness for the frame without the metal frame in the prior art. Obviously, the panel module of the invention use fewer components to achieve the required fixity and structure stiffness, which reduces the manufacturing cost of the components and is conducive to simplification on the assembly and improvement on the assembly quality.

Another objective of the invention is to provide a portable electronic apparatus equipped with the panel module of the invention. The portable electronic apparatus includes a casing. The panel module is fixed on the casing by the fixing parts. Similarly, the portable electronic apparatus also has the above-mentioned advantages of the panel module, which are not to be repeated more.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a portable electronic apparatus of a preferred embodiment according to the invention.

FIG. 2 is a partial exploded diagram of the panel module in FIG. 1.

FIG. 3 is a cross-section diagram of apart of the panel module in FIG. 1.

FIG. 4 is a schematic diagram of a panel module of another embodiment according to the invention.

### DETAILED DESCRIPTION

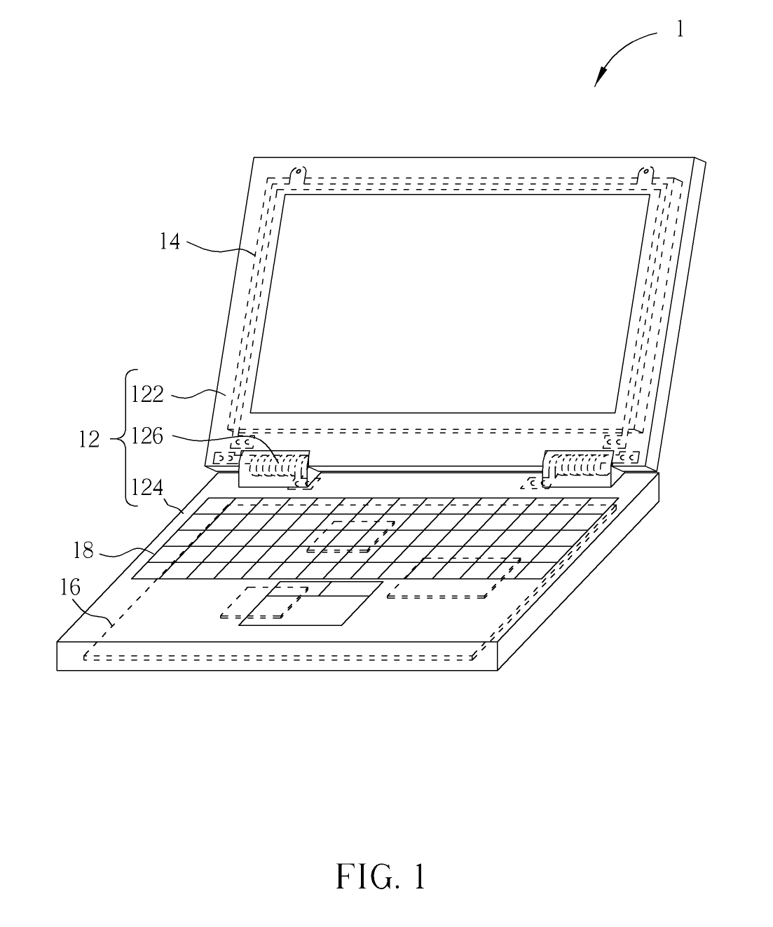

Please refer to FIG. 1 which is a schematic diagram of a portable electronic apparatus 1 of a preferred embodiment according to the invention. The portable electronic apparatus 1 is a notebook computer; however, the invention is not limited to this. The portable electronic apparatus 1 includes a casing 12 which includes an upper casing 122, a lower casing 124, and a hinge 126. The hinge 126 connects the upper casing 122 and a lower casing 124 so that the upper casing 122 and the lower casing 124 can rotate relatively. The portable electronic apparatus 1 also includes a panel module 14, a processing module 16, and an input module 18. The panel module 14 is disposed in the upper casing 122. The processing module 16 and the input module 18 are disposed in the lower casing 124. The processing module 16 is electrically connected to the input module 18 and the panel module 14. Thereby, a user can perform input through the input module 18 on the portable electronic apparatus 1, and the processing module 16 can control the panel module 14 to display and response the input by the user.

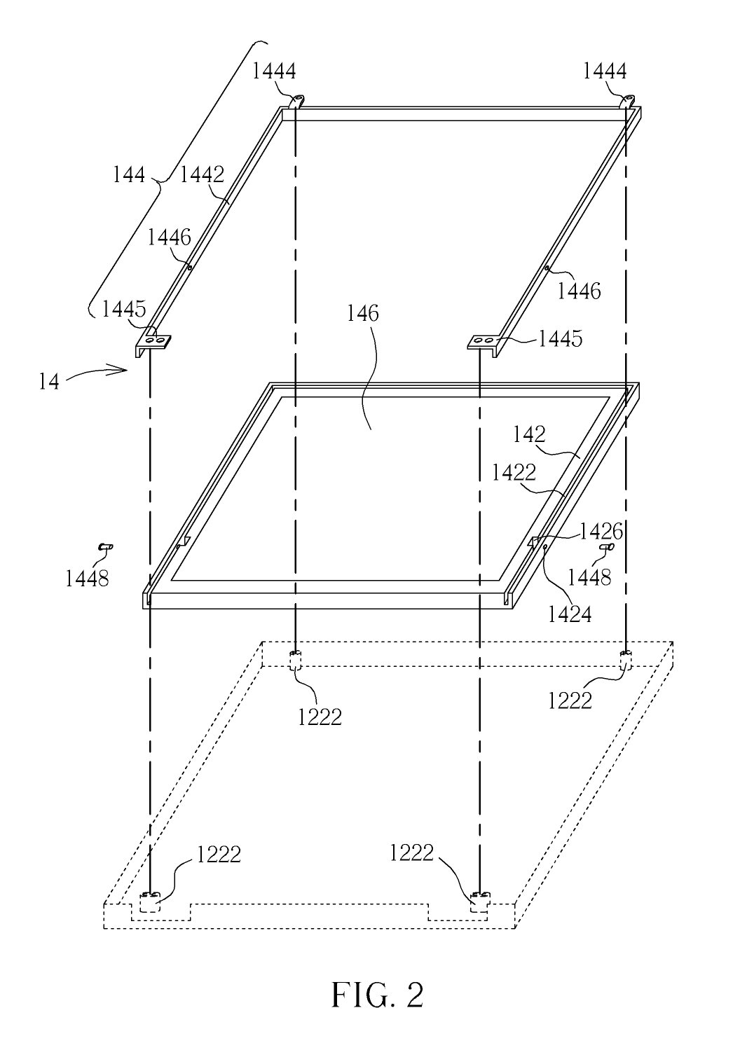

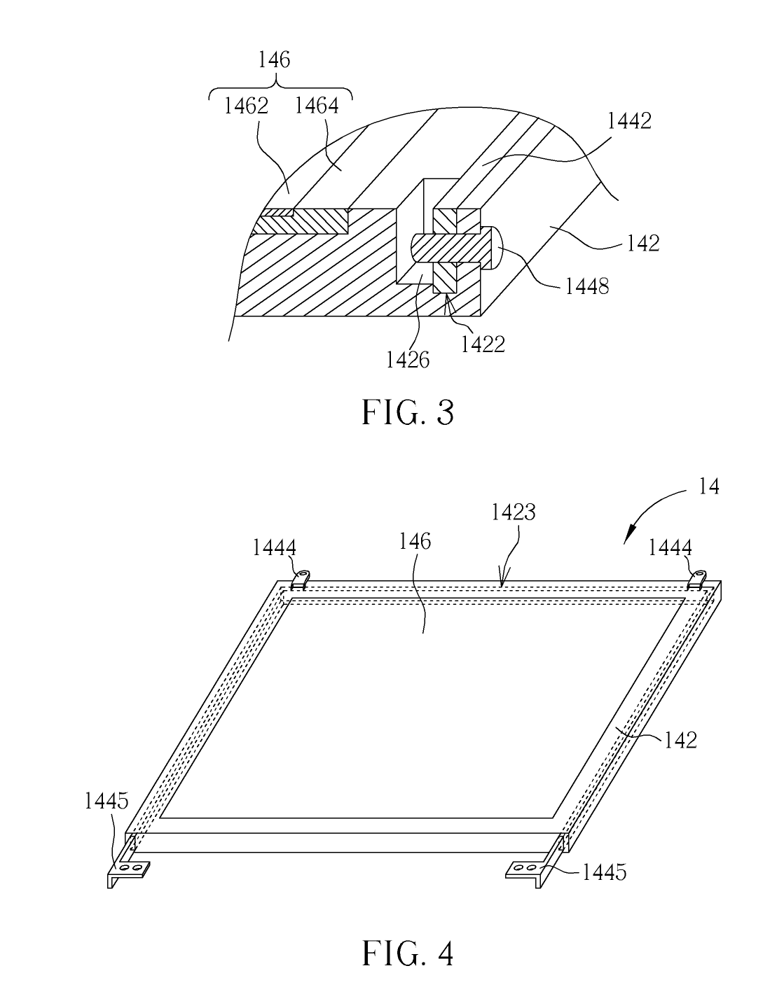

Please refer to FIG. 2 and FIG. 3. FIG. 2 is a partial exploded diagram of the panel module 14 in FIG. 1, and the upper casing 122 connected to the panel module 14 is shown in dashed lines. FIG. 3 is a cross-section diagram of a part of the panel module 14 in FIG. 1. The panel module 14 includes a frame 142, a bracket 144, and a display panel 146. The frame 142 includes a reverse U-shaped passage 1422 at the fringe portion thereof. A plurality of through holes 1424 are formed at side surfaces of the frame 142 to communicate with the reverse U-shaped passage 1422. The display panel 146 includes an LCD panel 1462 and a backlight panel 1464 (please referring to FIG. 3) and is fixed on the frame 142. The bracket 144 includes a reverse U-shaped body 1442 and a plurality of fixing parts 1444 and 1445 connected to the reverse U-shaped body 1442. The reverse U-shaped body 1442 thereon forms a plurality of threaded holes 1446 corresponding to the through holes 1424. The reverse U-shaped body 1442 is accommodated in the reverse U-shaped passage 1422. For each of the through holes 1424, a screw 1448 passes through the through hole 1424 from the outside of the frame 142 to be screwed into the corresponding threaded hole 1446. Therefore, the reverse U-shaped body 1442 is fixed on the frame 142 by the screws 1448, as shown in FIG. 3. In the embodiment, the frame 142 forms relief spaces 1426 at portions corresponding to the through holes 1424 so that protruded portions of the screws 1448 after screwed in the threaded holes 1446 can be accommodated in; however, the invention is not limited to this. For example, the length of the screw 1448 can be designed not to protrude out of the reverse U-shaped body 1442 after the screw 1448 is screwed in the threaded hole 1446. In addition, the reverse U-shaped body 1442 in the embodiment can be formed by bending a plate material . The threaded holes 1446 can be formed with a length larger than the thickness of the plate material by way of drawing, punching, threading, so as to enhance the strength and stability of the fixing by the screws 1448. At this case, the above relief spaces need to be reserved.

Furthermore, as shown in FIG. 2, the fixing part 1444 and 1445 protrudes out of the frame 142 and are fixed on fixing pillars 1222 of the upper casing 122, for example by screws. Thereby, the panel module 14 is disposed on the cupper casing 122 of the portable electronic apparatus 1 through the fixing parts 1444 and 1445. In addition, in the embodiment, the rotatable mechanism and the supporting structure are realized on the upper casing 122 and the lower casing 124 through the hinge 126. The panel module 14 fixed on the upper casing 122 rotates together with the upper casing 122, so the fixing part 1445 of the panel module 14 can be also fixed on a side of the hinge 126 for enhancing the stability of the upper casing 122 and the panel module 14 during rotating.

It is added that, in the embodiment, the frame 142 is made of engineering plastic and the bracket 144 is made of metal; however, the invention is not limited to this. The reverse U-shaped body 1442 thereon can form a strengthened structure for enhancing the stiffness of its structure, for example by forming rib structures at bended portions. The above embodiment is demonstrated by a notebook, but the invention is also applied to tablet computer. For the latter case, the portable electronic apparatus includes a single casing in principle. All components are disposed in the casing. The input module of the portable electronic apparatus is a touch panel and integrated into the panel module thereof; that is, the panel module provides the functions of displaying and inputting simultaneously.

In addition, in the above embodiment, the reverse U-shaped passage 1422 for accommodating the bracket 144 is a slot passage, so that the reverse U-shaped body 1442 can be placed downward into the reverse U-shaped passage 1422. However, in practice, the reverse U-shaped passage 1422 is not limited to a slot passage. Please refer to FIG. 4, which is a schematic diagram of a panel module 14 of another embodiment according to the invention. For the panel module 14 in FIG. 4, in logic, the reverse U-shaped passage 1423 is a through hole with rectangle section, which the reverse U-shaped body 1442 is accommodated in. The reverse U-shaped passage 1423 only needs to form openings at portions for the fixing parts 1444 and 1445 to protrude in principle, and the other portions encapsulates the reverse U-shaped body 1442. Thereby, the purpose of jointing the bracket 144 and the frame 142 can be achieved without the fixing by screws, and the enough strength and stability of the jointing is also provided. In practical manufacturing, the above structure can be realized by insert molding. In this casing, the section of the bracket 144 can be any shape to enhance the geometric constraint between the bracket 144 and the frame 142.

Based on the above explanation, the panel module of the invention uses the reverse U-shaped bracket which itself has a certain degree of stiffness and also uses the reverse U-shaped passage of the frame to accommodate the bracket. It makes the bracket and the frame jointed tightly. The bracket is used to provide the stiffness required by the frame (and the panel with layer structure fixed thereon) and is also used to fix the whole panel module in the electronic apparatus through the fixing parts of the bracket. Therefore, the reverse U-shaped bracket of the invention cannot be replaced individually with either the metal frame or the bracket for connecting and fixing in the prior art. In other words, the invention uses a single member to achieve the effect by at least two components in the prior art, which not only reduces the manufacturing cost of components but also is conducive to simplification on the assembly and improvement on the assembly quality.

Those skilled in the art will readily observe that numerous modifications and alterations of the device and method may be made while retaining the teachings of the invention.

What is claimed is:

1. A panel module, disposed in an electronic apparatus, comprising:
a frame, comprising a reverse U-shaped passage; and
a bracket, comprising a reverse U-shaped body and a plurality of fixing parts connected to the reverse U-shaped body, the reverse U-shaped body being accommodated in the reverse U-shaped passage, the fixing parts protruding out of the frame;
wherein, the panel module is disposed on a casing of the electronic apparatus by the fixing parts.

2. The panel module of claim 1, wherein the frame is made of engineering plastic.

3. The panel module of claim 2, wherein the bracket is made of metal.

4. The panel module of claim 1, wherein the reverse U-shaped body is fixed on the frame by a plurality of screws.

5. The panel module of claim 4, wherein a plurality of through holes are formed on a side of the frame to communicate with the reverse U-shaped passage, the reverse U-shaped body thereon forms a plurality of threaded holes corresponding to the through holes, and the screws are screwed from an outside of the frame past the through holes into the corresponding threaded holes.

6. The panel module of claim 1, wherein the reverse U-shaped body is embedded in the reverse U-shaped passage.

7. The panel module of claim 1, further comprising a display panel, fixed on the frame.

8. A portable electronic apparatus, comprising:
a casing; and
a panel module as claim 1, the panel module being fixed on the casing by the fixing parts.

9. The portable electronic apparatus of claim 8, wherein the casing comprises an upper casing, a lower casing, and a hinge connecting the upper casing and the lower casing, the panel module is disposed in the upper casing, and the bracket is fixed on the upper casing.

10. The portable electronic apparatus of claim 9, wherein the panel module comprises a display panel, fixed on the frame, the portable electronic apparatus further comprises a processing module and an input module, disposed in the lower casing, and the processing module is electrically connected to the input module and the panel module respectively.
